(19) United States
(12) Patent Application Publication
(10) Pub. No.: US 2017/0064842 A1
(43) Pub. Date: Mar. 2, 2017

(54) SCREWLESS THREE PIECE VERTICAL ELECTRONIC DEVICE

(71) Applicant: THOMSON LICENSING, Issy-les Moulineaux (FR)

(72) Inventor: William Phillip DERNIER, Indianapolis, IN (US)

(73) Assignee: Thomson Licensing, Issey-les Moulineaux (FR)

(21) Appl. No.: 15/307,431

(22) PCT Filed: Feb. 26, 2015
(86) PCT No.: PCT/US15/17784

§ 371 Date: Oct. 28, 2016

Related U.S. Application Data
(60) Provisional application No. 61/989,600, filed on May 7, 2014.

(51) Int. Cl. H05K 5/00; H05K 5/02

(52) U.S. Cl. CPC H05K 5/0013; H05K 5/0208; H05K 5/0252; H05K 5/0221; H05K 5/0217

(57) ABSTRACT

An electronic device and methods for assembling and disassembling the same are provided. The electronic device has a vertical orientation and has an outer casing that includes a case bottom piece, a case top front piece and a case top back piece. The electronic device further comprises a screwless engagement structure for attaching the case top front piece to the case top back piece to form a top structure. The electronic device also comprises a plurality of screwless clip and spring mechanisms for attaching the top structure to the case bottom piece.

### CROSS-REFERENCE TO RELATED APPLICATIONS

This application claims the benefit of U.S. Provisional Application Ser. No. 61/989,600, filed May 7, 2014, which is incorporated by reference herein in its entirety.

### TECHNICAL FIELD

The present principles relate generally to electronics and, more particularly, to an electronic apparatus and an associated disassembly release tool designed to quickly and safely disassemble the electronic apparatus.

### BACKGROUND

Electronic apparatuses or devices such as set-top boxes are typically assembled apparatuses having a plurality of walls wherein at least one of the walls is secured with a plurality of screws. Unfortunately, gaining access to the interior components of these devices requires removing the plurality of screws which often requires excessive handling of the device. The excessive handling often will involve changing the orientation of the device, such as by turning the devices upside down or placing it on its sides, to find each of the screws. This is then followed by disassembling the device by removal of one screw at a time with the device being upside down or on its side. This excessive handling of the device increases the chances of damaging the interior components because each motion of the device jars the components. Additionally, the removal and reengaging of the screws presents the opportunity for scratching the device or stripping threads of the screws.

In light of the fact that interior components of electronic devices often need to be accessed and that accessing the interior components can place the interior components at risk of damage or place the electronic device at risk for scratches, a need exists for an improved electronic device structure and method for opening the electronic device which is fast, simple, and safe.

To meet this need one known system is disclosed in WO2010008360A1. FIG. 1 is a perspective view of the apparatus according to WO2010008360A1 in a disassembled condition. An apparatus 1, such as a set top box, can include an enclosure having exterior walls defining an interior space, a top 10 having an interior surface 112 and a plurality of coupling clips 30 extending from the interior surface, and a base 5. The base 5 has an inner surface, a plurality of clip receiving members 20 extending from the inner surface which engage the coupling clips 30 to secure the top 10 to the base 5. The base 5 further includes at least one aperture 7 adapted to permit a release fixture having a plurality of decoupling members extending from a plate to simultaneously disengage the clip receiving members 20.

The method of assembling the apparatus 1 according to WO2010008360A1 includes: pushing a base 5 and top 10 together by applying a vertical force; simultaneously contacting coupling clips 30 of the top 10 with clip receiving members 20 of the base 5; laterally repositioning grasping portions of the coupling clips 30; and snapping the grasping portions into their initial lateral positions or some intermediate positions. There can be a lateral and vertical overlap of portions of the coupling clips 30 and part of the clip receiving members 20 which can cause the top 10 and base 5 to be disassembled. The clips and clip receiving members can be referred to as locks which can be unlocked by decoupling members The enclosure of FIG. 1 can house various electronic components such as processors, smart card assemblies, tuners, fans, storage devices, etc. These components can be supported in an interior support structure 60 which itself can have side walls and a base with appropriate apertures or component slots 9. The exterior walls can be a front wall 8, rear wall 6, side walls 4, a top 10 and a base 5.

The base 5 has an inner surface 13 opposite the outer surface and facing the top 10. The base 5 further includes a plurality of clip receiving members 20 extending from the inner surface 13, which are designed to secure the base 5 to the top 10. The base 5 further includes a series of apertures 7 which are associated with the clip receiving members 20 and are adjacent or near the clip receiving members 20.

The screwless locking features and release fixture concept disclosed in WO2010008360A1 works well for the basic electronic devices in which the electronic devices are generally short having wide horizontal bases and having two principal outer housing components with locking features (i.e., the top and bottom casing components).

In electronic devices in which the casings of the device are vertically tall or at least less horizontally oriented, the bases are generally narrow and there are two principal outer housing components with locking features, the concept disclosed in

WO2010008360A1 is not very practical. The reason is the locking mechanisms would need to be very long if apertures associates with the locking and unlocking features are in the base. If the apertures are placed on the vertical sides to permit shorter locking mechanisms and shorter unlocking features on an unlocking fixture, the apertures would then be unsightly, because in taller designs the vertical sides will tend to be viewable to the consumer. As such, the need for a locking and unlocking mechanism for tall or taller electronic devices which does not require long locking and unlocking features is needed.

Further, to eliminate the poor appearance of openings on the vertical or viewable surfaces in tall or taller electronic devices and to avoid using screws to lock such assemblies per consumer demand, the need for an improved locking and unlocking mechanism is needed.

Further, per consumer demand, a single step disassembly operation that incorporates a release fixture that is useable for taller electronic devices is desired which provides a means of safely and easily accessing the interior components of an electronic device without risk of damaging the components of the device. However, at the same time, what is needed is a solution that ensures that unauthorized access, e.g., by children, is substantially inhibited.

### SUMMARY

These and other drawbacks and disadvantages of the prior art are addressed by the present principles, which are directed to an electronic apparatus and an associated disassembly release tool designed to quickly and safely disassemble the electronic apparatus.

According to an aspect of the present principles, an electronic device 200 or a housing for an electronic device is provided having a vertical orientation and having an outer casing that includes a case bottom piece 213, a case top front piece 211 and a case top back piece 212. The electronic device further includes a screwless engagement structure 977 for attaching the case top front piece to the case top back piece 212 to form a top structure 210. The electronic device also includes a plurality of screwless clip and spring mechanisms 288 for attaching the top structure to the case bottom piece.

According to another aspect of the present principles, a method 2100 is provided for assembling an electronic device having a vertical orientation and having an outer casing that includes a case bottom piece, a case top front piece and a case top back piece. The method includes attaching 2110 the case top front piece to the case top back piece to form a top structure using a screwless engagement structure. The method further includes attaching 2120 the top structure to the case bottom piece using a plurality of screwless clip and spring mechanisms.

According to yet another aspect of the present principles, a method 2200 is provided for disassembling an electronic device having a vertical orientation and having an outer casing that includes a case bottom piece, a case top front piece and a case top back piece. For an assembled condition, wherein the case top front piece is attached to the case top back piece to form a top structure using a screwless engagement structure, and the top structure is attached to the case bottom piece using a plurality of screwless clip and spring mechanisms, the method includes moving 2210 a release fixture with release fingers vertically upward toward a bottom of the electronic device to simultaneously disengage a locking portion of each of the plurality of screwless clip and spring mechanisms to allow the case top front piece and the case top back piece to be removed upward from the case bottom piece. For the assembled condition, the method further includes sliding 2220 the case top front piece down with respect to the case top back piece to disengage the screwless engagement structure and separate the case top front piece from the case top back piece such that electronic components included within the outer casing can be accessed.

These and other aspects, features and advantages of the present principles will become apparent from the following detailed description of exemplary embodiments, which is to be read in connection with the accompanying drawings.

### BRIEF DESCRIPTION OF THE DRAWINGS

The present principles can be better understood in accordance with the following exemplary figures, in which:

FIG. 1 is a perspective view of a prior art horizontal oriented casing of an electronic device;

FIG. 2 is a perspective view of a vertically oriented electronic device 200, in accordance with an embodiment of the present principles;

FIG. 3 is a disassembled perspective view of the vertically oriented electronic device 200, in accordance with an embodiment of the present principles;

FIG. 4 is a perspective view of a retention clip 214, in accordance with an embodiment of the present principles;

FIG. 5 is a perspective view of the casing that shows how the pieces of the casing are assembled, in accordance with an embodiment of the present principles;

FIG. 6 is a perspective view of the casing that shows a case back retaining feature, in accordance with an embodiment of the present principles;

FIG. 7 is a perspective view of the casing that shows a cross-section of an interlock, in accordance with an embodiment of the present principles;

FIG. 8 is a perspective view of the casing that shows an opening on the case front, in accordance with an embodiment of the present principles;

FIG. 9 is a perspective view of the retaining features of the vertically oriented electronic device 200, in accordance with an embodiment of the present principles;

FIG. 10 is another perspective view of the retaining features of the vertically oriented electronic device 200, in accordance with an embodiment of the present principles;

FIG. 11 is a disassembled perspective view of the vertically oriented electronic device 200, in accordance with an embodiment of the present principles;

FIG. 12 is a bottom perspective view of the vertically oriented electronic device 200 and the metal retention clips 214, in accordance with an embodiment of the present principles;

FIGS. 13-15 are various views of the metal retention clips, in accordance with an embodiment of the present principles;

FIG. 16 is perspective views of the case bottom piece 213, in accordance with an embodiment of the present principles;

FIGS. 17 and 18 are perspective views showing how the bottom piece 213 engages the case top front piece and the case top back piece 212, in accordance with an embodiment of the present principles;

FIG. 19 is a bottom perspective view of the vertically oriented electronic device 200, in accordance with an embodiment of the present principles;

FIG. 20 is a view of the release fixture 300, in accordance with an embodiment of the present principles;

FIG. 21 is a flow diagram showing an exemplary method 2100 for assembling an electronic device having a case bottom piece, a case top front piece, and a case top back piece, in accordance with an embodiment of the present principles; and

FIG. 22 is a flow diagram showing an exemplary method 2200 for disassembling an electronic device having a case bottom piece, a case top front piece, and a case top back piece, in accordance with an embodiment of the present principles.

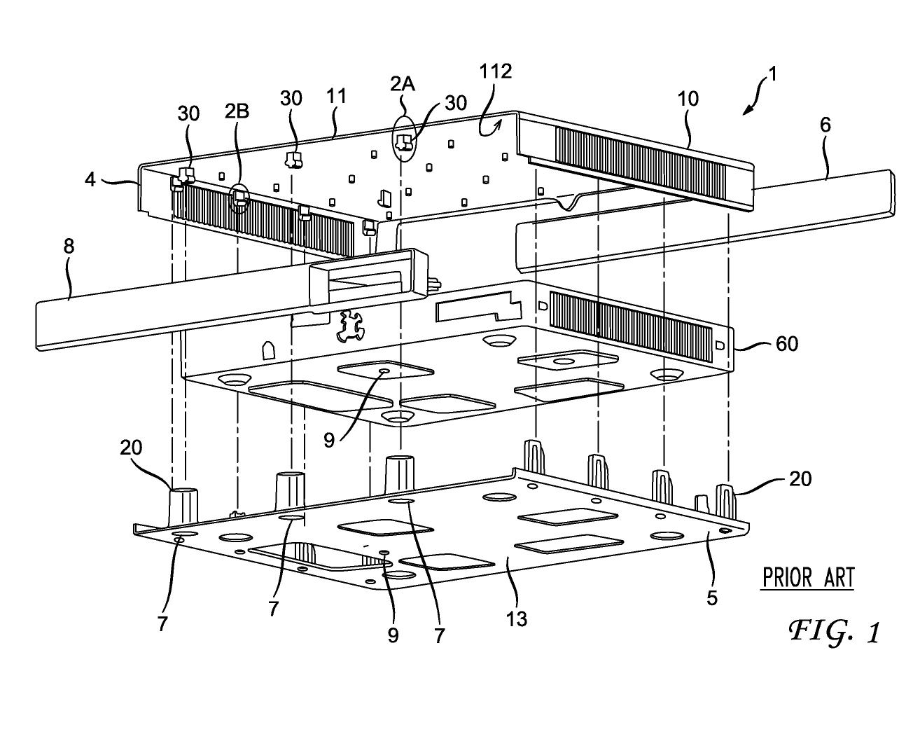

### DETAILED DESCRIPTION

The present principles are directed to an electronic apparatus and an associated disassembly release tool designed to quickly and safely disassemble the electronic apparatus.

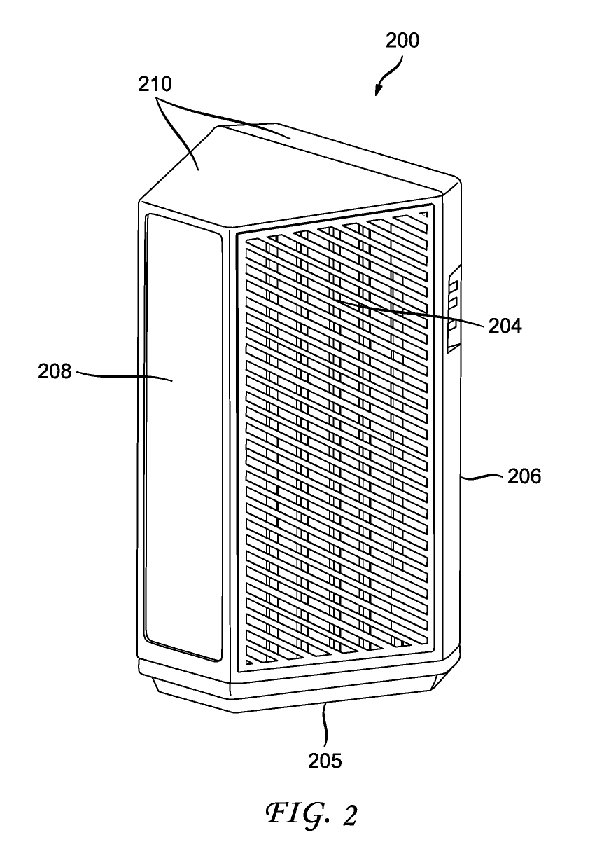

FIG. 2 shows a perspective view of the vertically oriented electronic device 200 having a top 210, a front wall 208, a rear wall 206, side walls 204, and a base 205, in accordance with an embodiment of the present principles.

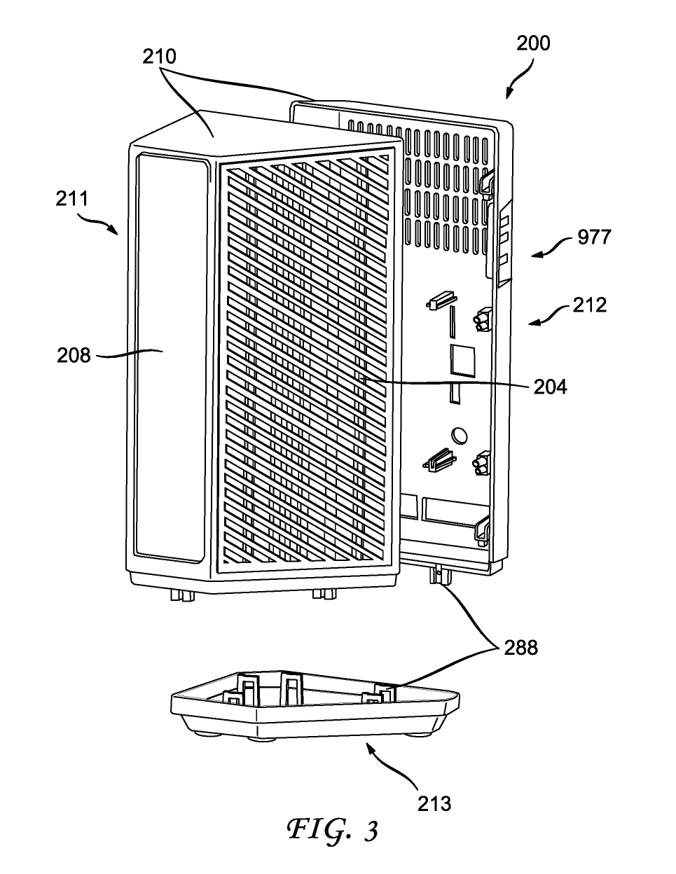

FIG. 3 shows the three principal pieces of the vertically oriented electronic device 200, in accordance with an embodiment of the present principles. The three pieces are the case bottom piece 213, the case top front piece 211, and the case top back piece 212.

FIG. 4 is a perspective view of a retention clip 214, which can be metal, that is utilized to engage and secure the case bottom piece 213 to the case top front piece 211 and/or the case top back piece 212, in accordance with an embodiment of the present principles.

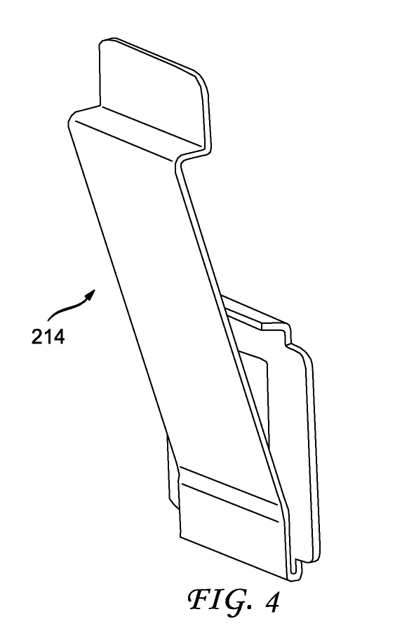

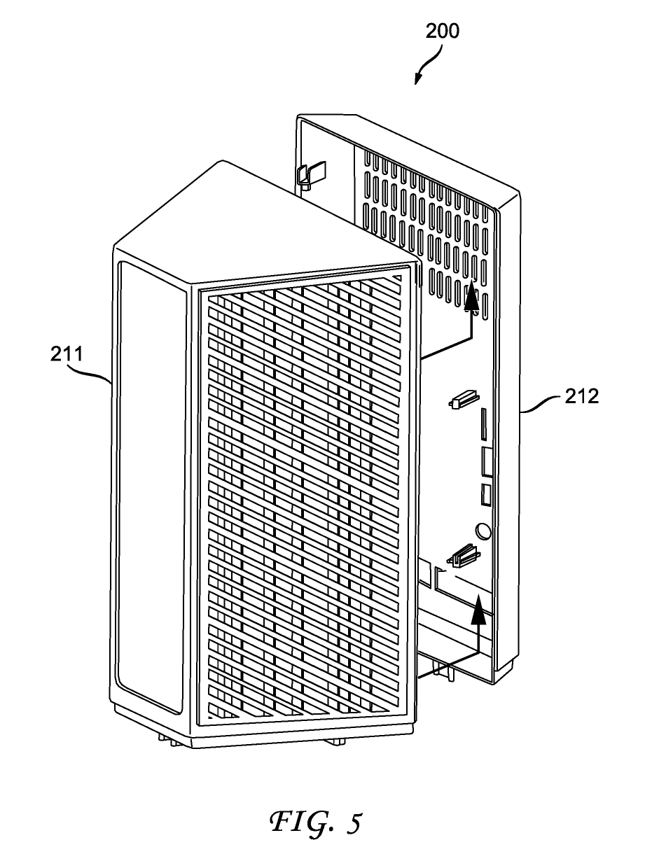

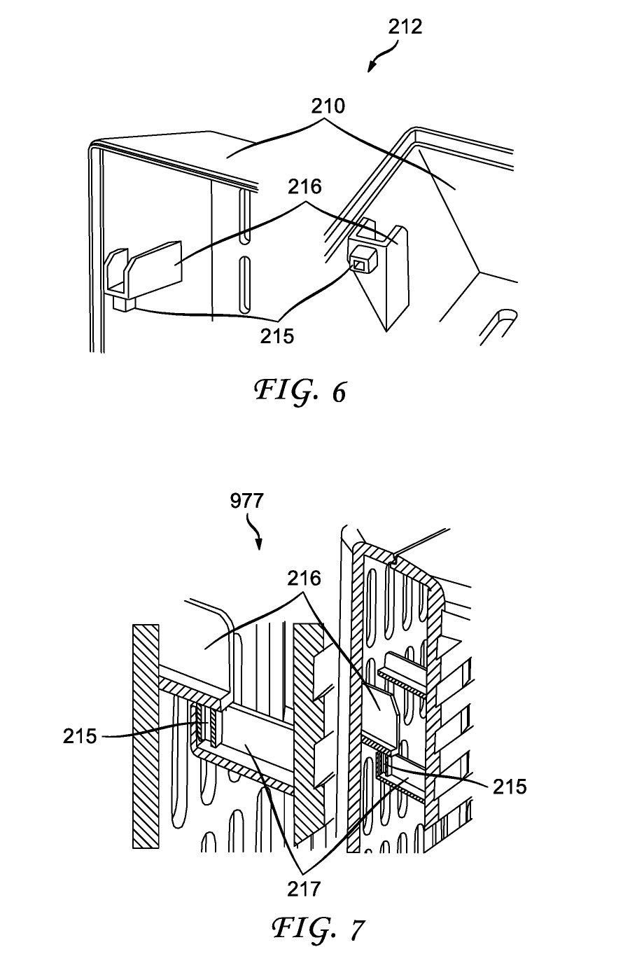

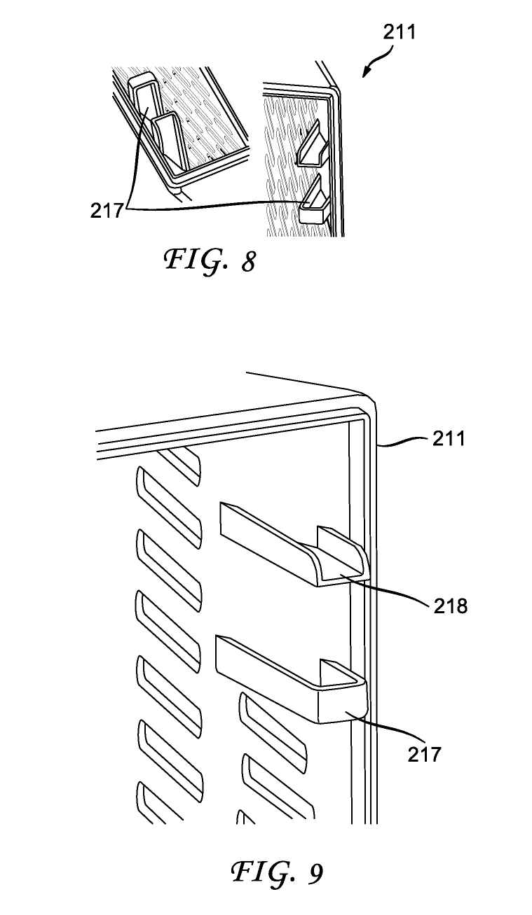

FIG. 5 shows how the case top front piece 211 is slid back onto case top back piece 212 of the electronic device 200, and then up into retaining features in order lock the two together such that internal electronic components can be housed therein when the assembly is finalized, in accordance with an embodiment of the present principles. FIGS. 6-8 show the specific engagement mechanism in which a protruding ledge 216 extends inwardly from the interior surface of one of the vertical walls of one of the pieces, in accordance with an embodiment of the present principles. The protruding ledge 216 includes protrusions 215 that engage protrusion receiving openings 217 on the case front piece 211. The protrusion receiving openings 217 are generally horizontal ledges that have upstanding peripheral walls to make a slot that can receive the protrusions 215. The slots can be oversized in the dimension that is perpendicular from the interior wall from which the ledge extends or along its long lateral axis. The slot can be narrow along the dimension parallel to the wall or along the ledge's short lateral axis to snuggly fix the protrusions 215. The protruding ledge 216, the protrusions 215, and the protrusion receiving openings 217 form a screwless engagement structure.

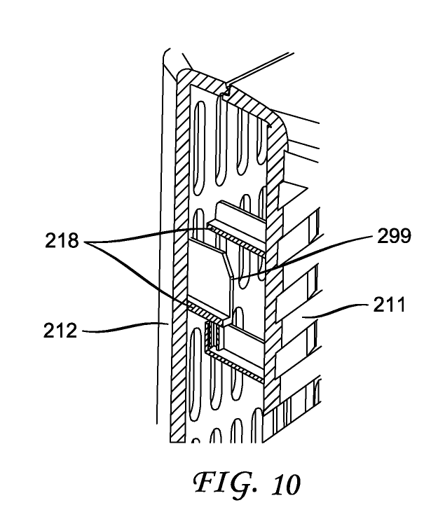

FIGS. 9 and 10 show further perspective views of the retaining features that are used to engage the case top front piece 211 with the case top back piece 212, in accordance with an embodiment of the present principles. FIG. 9 shows ribs 218 that are positioned above the protrusion receiving openings 217 and also extend inwardly from the interior surface of one of the vertical walls of the front piece 211. The ribs 218 would interfere with the case rear retention feature if an assembly start position is attempted that is too low. FIG. 10 shows that a chamfer 299 guides the case top 210 to an acceptable start location. Rib 218 prevents case front from starting in too low of a position by preventing excessive case travel which can damage components.

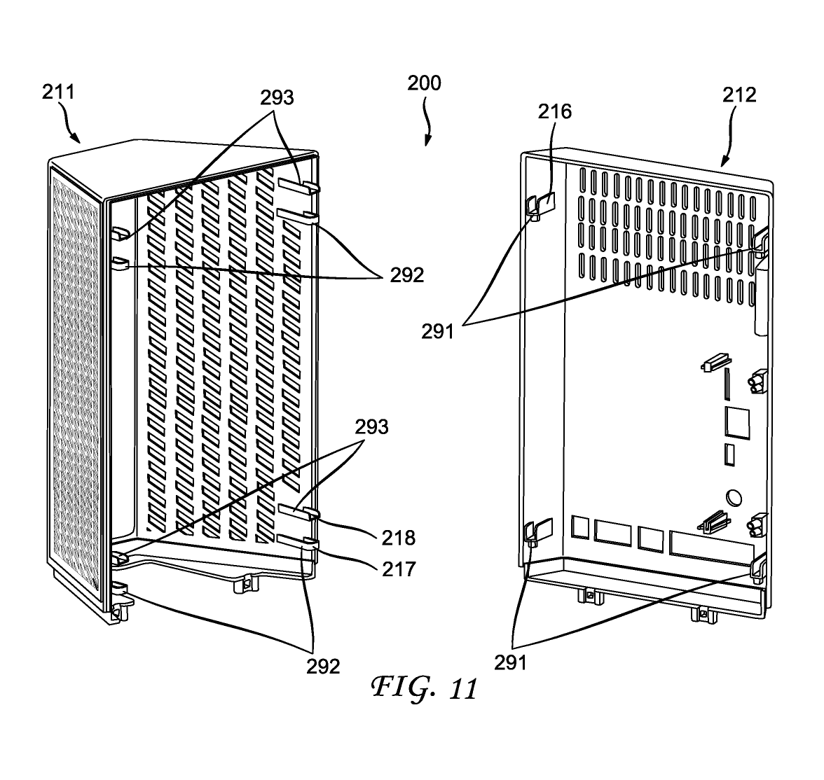

FIG. 11 is a disassembled perspective view of the vertically oriented electronic device 200 showing the interior walls of the front piece 211 and the case top back piece 212 of the electronic device 200, in accordance with an embodiment of the present principles. The retention protrusions 291, the retention openings 292, and over travel prevention portions 293 are shown in FIG. 11.

It should be noted that the device 200 can include electronic components such as circuit boards, hard drives, antennae, etc. and that the electronic components can be connected to a panel jack. The panel jack can be on the rear wall 206 or can be a part of the rear wall. The rear wall 206 can be part of the case top back piece 212 in which some of the lower rectangular features on the piece 212 in FIG. 11 can represent a panel jack.

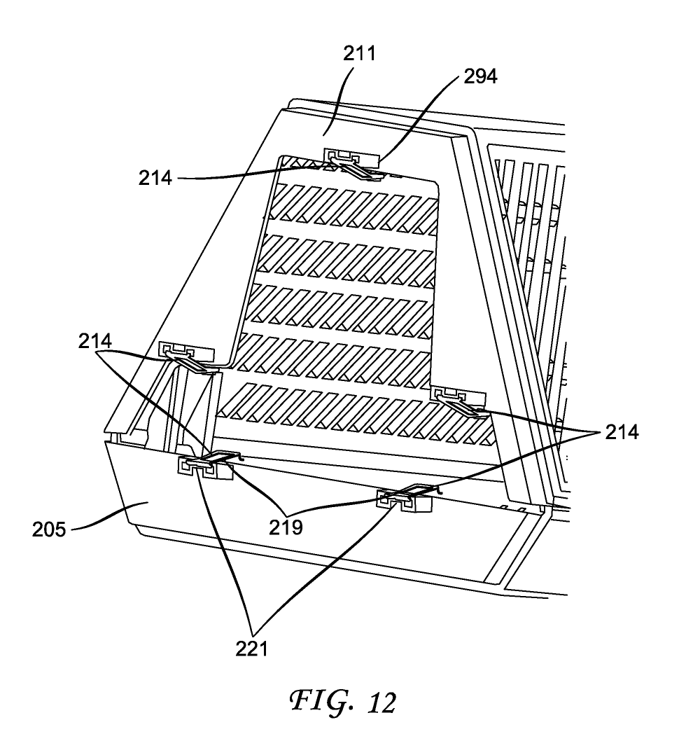

FIG. 12 is a bottom perspective view of the vertically oriented electronic device 200 in which the case bottom piece 213 is not attached, in accordance with an embodiment of the present principles.

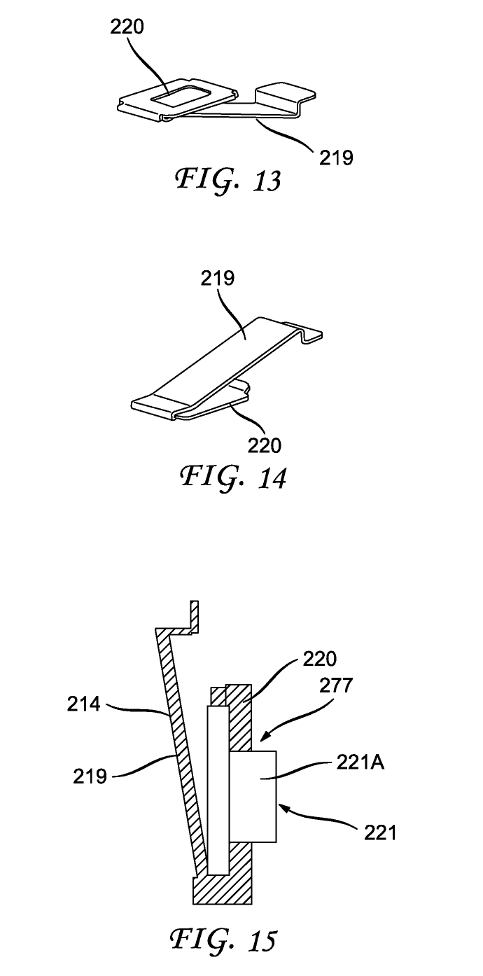

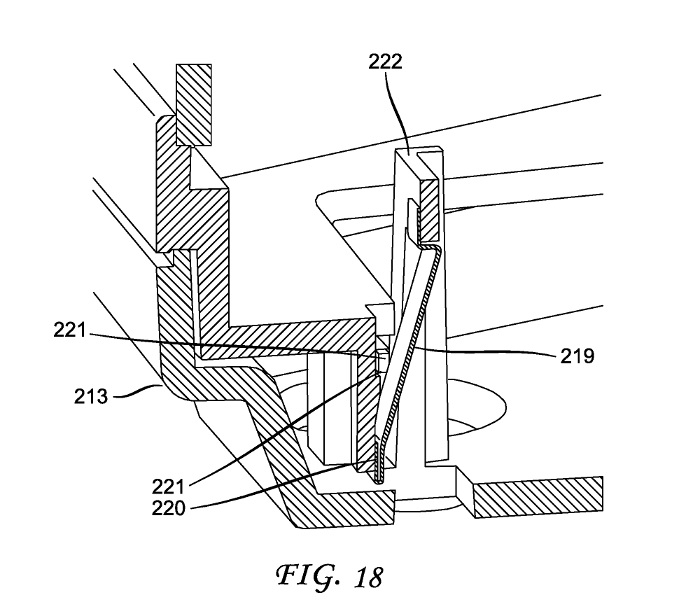

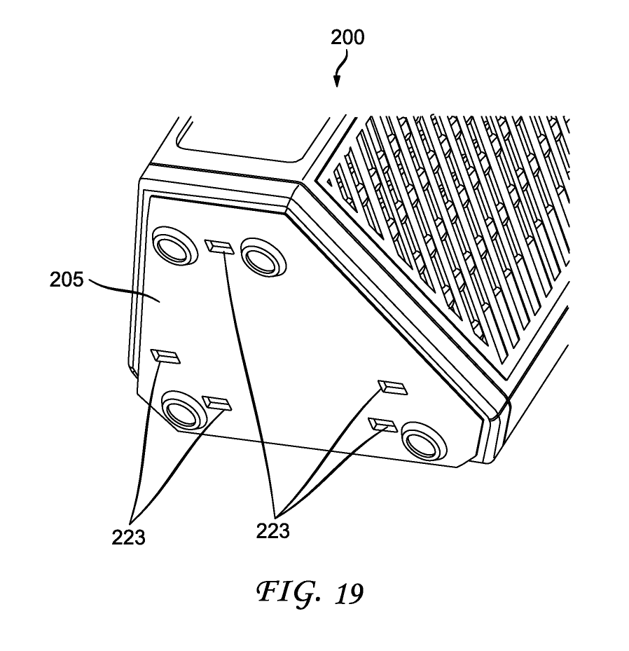

FIGS. 13-15 are various views of the metal retention clips 214, in accordance with an embodiment of the present principles. The views show that the front piece 211 and the case top back piece 212 can be attached to one another and can then be attached to the case bottom piece 213 using the metal retention clips 214. The metal retention clips 214 are retained by features on the case top front piece 211 and the case top back piece 212. The clips 214 are generally V-shaped in which there is an anchor portion 220 which is one side of the V-shape. The anchor portion 220 can have a rectangular planar shape and have an aperture 277 that fits into an anchor base 221 of the case top front piece 211 and the case top back piece 212. FIG. 15 shows how the aperture 277 of anchor portion 220 engages a protrusion 221A in the anchor base 221 such that an inward pointing ledge at the top of the anchor portion 220 grasps a top portion of the anchor base 221 and the bottom inner wedge grasps the bottom portion of the anchor base 221 to the secure the retention clip 214. This permits the locking portion 219 of the clip 214, which is the other side of the V-shape, to engage with features of the bottom piece 213 to close or assemble the electronic device 200. In particular, the top of the locking portion 219 can have a horizontal ledge that extends inwardly to contact a bottom surface of the clip engaging features 222 and the locking portion 219 can further have an upward extension at the edge of the ledge to engage an edge of the bottom surface of the feature 222 as the outward spring force of spring 214 cause the locking portion to move outward to engage the feature 222 as shown in FIG. 18. Although a V-shape is shown, a U-shape could be employed as well and both sides of the V or U-shape part can have different heights.

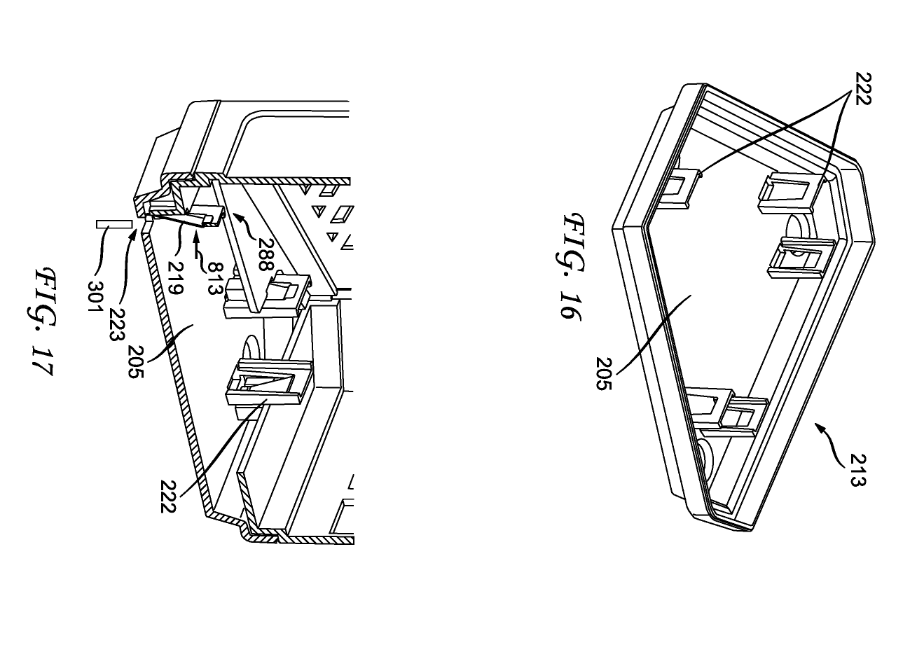

FIG. 16 is a perspective view of the case bottom piece 213 which shows the base 205 and clip engaging features 222 that extend vertically upward from the bottom piece 213, in accordance with an embodiment of the present principles. The clip engaging features 222 are designed to engage the locking portion 219 of the clips 214 on the case front 211 and the case top back piece 212. A screwless clip and spring mechanism 288 is formed from the clips 214 and clip engaging features.

FIGS. 17 and 18 are perspective views showing how the case bottom piece 213 engages the case top front piece 211 and the case top back piece 212, in accordance with an embodiment of the present principles. Release finger 301 pushes locking portion inward to disengage the locking portion 219 as it enters aperture 223

FIG. 19 is a bottom perspective view of the vertically oriented electronic device 200, in accordance with an embodiment of the present principles.

FIG. 20 is a view of a release fixture 300, in accordance with an embodiment of the present principles. FIGS. 19 and 20 show release aperture 223 in base 205 which permits a release finger 301 on a base of a release fixture 300 to enter the release aperture 223 to push the locking portion 219 inward toward the anchor portion 220 to remove the top portion of the locking portion 219 off of the engaging feature 222. This can be understood also with reference to FIG. 18 in which the release finger 301 (not shown in FIG. 301) will contact the outer edge of the locking portion 219 move the locking portion 219 away from engaging feature 222.

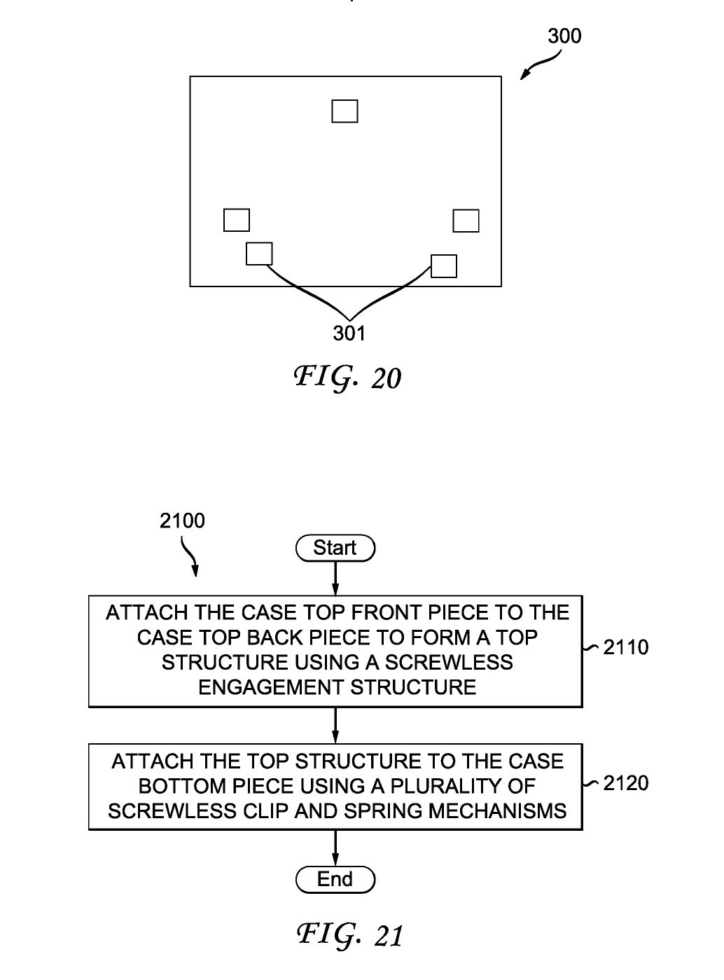

FIG. 21 is a flow diagram showing an exemplary method 2100 for assembling an electronic device having a case bottom piece, a case top front piece, and a case top back piece, in accordance with an embodiment of the present principles. At step 2110, attach the case top front piece 211 to the case top back piece 212 to form a top structure 210 using a screwless engagement structure 977. At step 2120, attach the top structure 210 to the case bottom piece 213 using a plurality of screwless clip and spring mechanisms 288.

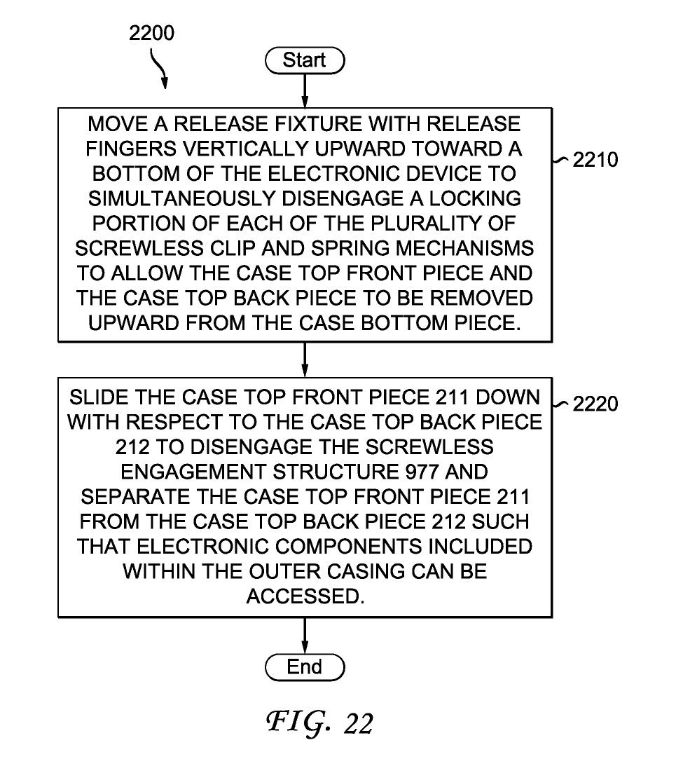

FIG. 22 is a flow diagram showing an exemplary method 2200 for disassembling an electronic device having a case bottom piece, a case top front piece, and a case top back piece, in accordance with an embodiment of the present principles. The method 2200 is applied to an assembled condition, wherein the case top front piece is attached to the case top back piece 212 to form a top structure 210 using a screwless engagement structure 977, and the top structure is attached to the case bottom piece using a plurality of screwless clip and spring mechanisms 288. At step 2210, move a release fixture 300 with release fingers 301 vertically upward toward a bottom of the electronic device to simultaneously disengage a locking portion 219 of each of the plurality of screwless clip and spring mechanisms 288 to allow the case top front piece 211 and the case top back piece 212 to be removed upward from the case bottom piece 213. At step 2220, slide the case top front piece 211 down with respect to the case top back piece 212 to disengage the screwless engagement structure 977 and separate the case top front piece 211 from the case top back piece 212 such that electronic components included within the outer casing can be accessed.

The electronic device 200 can be a set-top box or the like and can be vertically oriented such that the height of the device is higher than the width of the front vertical surface and/or the rear vertical surface and/or the lateral depth. The lateral cross section can be a quadrilateral shape in which the front and back are parallel and the side surfaces are not parallel to one another. The device can be designed such that the release fixture and release fingers move vertically upward toward the bottom of the device to simultaneously disengage the plurality of the locking portions to allow the case top front piece 211 and the case top back piece 212 to be remove upward from the case bottom piece 213. The case top front piece 211 and the case top back piece 212 can then further be detached from one another by moving the case top in a motion oppose to that shown in FIG. 5 to attach the two pieces (case top front piece 211 and case top back piece 212). With the two pieces 211 and 212 attached, the assembly can be reassembled or assembled by aligning the clip engaging features 222 with the clip 214 when the release fixture is removed or not present.

Thus, a method of retaining three parts together without screws to form a complete casing that is designed to enable a release tool to access the interior. More particularly, the only access to non-destructively open the casing can be from a bottom facing surface. This ensures that no access holes are observed on viewable appearance surfaces, which are generally the vertical surfaces and the top. The focus of the disclosure is for casings having a given shape that is a vertically oriented tall structure which would not mold easily as a two piece design and meet consumer demand. However, with such a form, a three piece design is disclosed that has release latches for front and back case pieces that do not require unsightly access holes on the vertical viewable surfaces and top, and advantageously meet consumer preference and include pieces that mold more conveniently.

The present description illustrates the present principles. It will thus be appreciated that those skilled in the art will be able to devise various arrangements that, although not explicitly described or shown herein, embody the present principles and are included within its spirit and scope.

All examples and conditional language recited herein are intended for pedagogical purposes to aid the reader in understanding the present principles and the concepts contributed by the inventors to furthering the art, and are to be construed as being without limitation to such specifically recited examples and conditions.

Moreover, all statements herein reciting principles, aspects, and embodiments of the present principles, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Although the illustrative embodiments have been described herein with reference to the accompanying drawings, it is to be understood that the present principles is not limited to those precise embodiments, and that various changes and modifications may be effected therein by one of ordinary skill in the pertinent art without departing from the scope or spirit of the present principles. All such changes and modifications are intended to be included within the scope of the present principles as set forth in the appended claims.

1. An electronic device comprising:
an outer casing having a vertical orientation, the outer casing includes a case bottom piece, a case top front piece and a case top back piece;
a screwless engagement structure for attaching the case top front piece to the case top back piece to form a top structure; and
a plurality of screwless clip and spring mechanisms for attaching the top structure to the case bottom piece.

2. The electronic device of claim 1, wherein the screwless engagement structure comprises:
a plurality of ledges protruding from the case top back piece, each having an engagement protrusion; and
a plurality of protrusion openings, each for receiving the engagement protrusion from a respective one of the plurality of ledges.

3. The electronic device of claim 1, wherein each of the plurality of screwless clip and spring mechanisms comprise a respective retention clip and a respective clip engaging feature.

4. The electronic device of claim 3, wherein the respective clip engaging feature has an anchor base with a protrusion, and the respective retention clip has a locking portion and an anchor portion with an anchor aperture, the protrusion for fitting into the anchor aperture.

5. The electronic device of claim 1, wherein each of the plurality of screwless clip and spring mechanisms comprise a respective retention clip on the case top front piece or the case top back piece and a respective clip engaging feature on the case bottom piece.

6. The electronic device of claim 1, wherein the clip and spring mechanism is positioned at or near a bottom of the top structure, and the clip and spring mechanism extends less than or up to a quarter of a height of the electronic device.

7. The electronic device of claim 1, wherein the electronic device has a height that is higher than a width of at least one of a front vertical surface of the electronic device, a rear vertical surface of the electronic device, and a lateral depth of the electronic device.

8. The electronic device of claim 1, wherein the electronic device has a shape in which a top plan view cross section forms a quadrilateral in which a front portion and a back portion are parallel to each other and side portions are not parallel to each other.

9. The electronic device of claim 1, wherein the electronic device is configured such that a release fixture with release fingers, when moved vertically upward toward a bottom of the electronic device, simultaneously disengages a locking portion of each of the plurality of screwless clip and spring mechanisms to allow the case top front piece and the case top back piece to be removed upward from the case bottom piece such that electronic components included within the outer casing can be accessed.

10. The electronic device of claim 9, wherein the electronic device further comprises release apertures on the bottom of the electronic device for permitting the release fingers to pass there through to disengage the locking portion of each of the plurality of screwless clip and spring mechanisms.

11. The electronic device of claim 10, wherein each of the plurality of screwless clip and spring mechanisms comprise a respective clip engaging feature and a respective retention clip, the respective clip engaging feature having an anchor base with a protrusion, and the respective retention clip having the locking portion and an anchor portion with an anchor aperture, the protrusion for fitting into the anchor aperture.

12. The electronic device of claim 11, wherein the release fingers pass through the bottom of the electronic device to push the locking portion away from the anchor portion and disengage the protrusion from the anchor aperture.

13. The electronic device of claim 9, wherein the release fingers pass through the bottom of the electronic device to push the locking portion of each of the plurality of screwless clip and spring mechanisms inward towards a respective anchor portion of each of the plurality of screwless clip and spring mechanisms to remove a top portion of the locking portion from a respective clip engaging feature of each of the plurality of screwless clip and spring mechanisms.

14. The electronic device of claim 1, further comprising protrusions on the case top back piece for interfacing with openings on the case top front piece to prevent an incorrect start of assembly position between the case top back piece and the case top front piece.

15. The electronic device of claim 1, wherein the electronic device is a set top box.

16. A housing for an electronic device having a vertical orientation comprising:
an outer casing that includes a case bottom piece, a case top front piece and a case top back piece;
a screwless engagement structure for attaching the case top front piece to the case top back piece to form a top structure; and
a plurality of screwless clip and spring mechanisms for attaching the top structure to the case bottom piece.

17. The housing of claim 16, wherein the screwless engagement structure comprises:
a plurality of ledges protruding from the case top back piece, each having an engagement protrusion; and
a plurality of protrusion openings, each for receiving the engagement protrusion from a respective one of the plurality of ledges.

18. The housing of claim 16, wherein each of the plurality of screwless clip and spring mechanisms comprise a respective retention clip and a respective clip engaging feature.

19. The housing of claim 16, wherein the clip and spring mechanism is positioned at or near a bottom of the top structure, and the clip and spring mechanism extends less than or up to a quarter of a height of the housing.

20. The housing of claim 16, wherein the housing has a height that is higher than a width of at least one of a front vertical surface of the housing, a rear vertical surface of the housing, and a lateral depth of the housing.
